(19) United States
(12) Patent Application Publication
(10) Pub. No.: US 2026/0372014 A1
(43) Pub. Date: Nov. 19, 2026

(54) METHOD AND SYSTEM FOR DETECTING WAFER WOBBLE

(71) Applicant: GSF solution Co., Ltd., Cheongju-si (KR)

(72) Inventors: Donghyun KIM, Seongnam-si (KR); Seonghyeon YOON, Seongnam-si (KR)

(73) Assignee: GSF solution Co., Ltd., Cheongju-si (KR)

(21) Appl. No.: 19/414,451

(22) Filed: Dec. 10, 2025

(30) Foreign Application Priority Data
May 15, 2025 (KR) 10-2025-0063289
May 15, 2025 (KR) 10-2025-0063290
May 15, 2025 (KR) 10-2025-0063291
May 15, 2025 (KR) 10-2025-0063292

(51) Int. Cl. H10P 74/20; G06T 7/90; H10P 72/00

(52) U.S. Cl. CPC H10P 74/203; G06T 7/90; H10P 72/0606; G06T 2207/20076; G06T 2207/20081; G06T 2207/30148

(57) ABSTRACT

Proposed are a method and a system for detecting wobbling of a wafer rotating at high speed in semiconductor equipment. A wafer wobble detection method includes acquiring a wafer surface image to include a reflection image, where a fixed object installed inside equipment and having a fixed position is reflected on a surface of a wafer; and detecting wobbling of the wafer by analyzing a position of the reflection image that moves due to wobbling in the acquired image, wherein analyzing the position of the reflection image includes setting a detection region at a predetermined position of an image and setting a color of the reflection image as a detection color, and calculating a ratio of a detection color region included in the detection region, wherein the detection region is set on the basis of the position of the reflection image.

### CROSS REFERENCE TO RELATED APPLICATION

The present application claims priority to Korean Patent Application Nos. 10-2025-0063289, 10-2025-0063290, 10-2025-0063291, and 10-2025-0063292, each filed on May 15, 2025, the entire contents of which are incorporated herein for all purposes by this reference.

### BACKGROUND

### Technical Field

The present disclosure relates to a method and a system for detecting wobbling of a wafer and, more particularly, to a method and a system for detecting wobbling of a wafer rotating at high speed in semiconductor equipment.

### Description of the Related Art

In general, in semiconductor manufacturing processes, much of the semiconductor equipment used to perform a specific process on a semiconductor wafer performs the process while rotating the wafer at high speeds. For example, a wafer cleaning apparatus operates by discharging a cleaning solution onto the surface of a wafer while the wafer is rotating.

In this way, wafers rotating at high speeds in semiconductor equipment can wobble due to factors such as vibrations from the equipment. At this time, the wobbling within a predetermined range does not affect the process, but excessive wobbling can cause process issues. Excessive wobbling may be caused by issues within the equipment itself, such as the rotating equipment, or may occur when the wafer to be processed is not properly mounted within the equipment.

To prevent such problems, technologies have been developed that acquire wobbling information on wafers and compare the same with standard information to determine operational errors in the process of performing preventive or emergency maintenance on semiconductor equipment.

However, when excessive wobbling is occurring before maintenance is performed, it is difficult to check about it, and when the problem originates from the semiconductor equipment itself, all wafers put into the process should be discarded until maintenance is performed or until defects on the wafer are discovered. In addition, even when a problem arises during the wafer mounting process rather than the semiconductor equipment itself, it can still cause malfunctions in precision equipment, so there is a need for technologies capable of detecting wafer wobbling in real time while semiconductor equipment is in operation.

### Related Art Documents

### Patent Document

(Patent Document 1) Korean Patent No. 10-1681517

### SUMMARY

The present disclosure is devised to solve the problem of the prior art described above, and aims to provide a method and a system capable of detecting wobbling of wafers in the process of performing work in semiconductor equipment.

A wafer wobble detection method for achieving the above objective according to the present disclosure is a wafer wobble detection method applicable to semiconductor equipment that performs a process while rotating an internally mounted wafer, the method including: acquiring a wafer surface image to include a reflection image where a fixed object installed inside equipment and having a fixed position is reflected on a surface of a wafer; and detecting wobbling of the wafer by analyzing a position of the reflection image that moves due to wobbling in the acquired image, wherein analyzing the position of the reflection image includes setting a detection region at a predetermined position of an image and setting a color of the reflection image as a detection color, and calculating a ratio of a detection color region included in the detection region, wherein the detection region is set on the basis of the position of the reflection image.

In the process of analyzing the position of the reflection image, the image may be an image converted to a gray scale, and the detection color may be the color of the reflection image converted to the gray scale.

The method may further include adjusting the converted grayscale to a reference scale, wherein the reference scale is set on the basis of a color of the wafer and the color of the wafer in a captured image is adjusted to match the reference scale.

The image may be an image to which image interpolation is applied.

Detecting the wobbling may include acquiring a first data on the position of the reflection image, producing a second data by correcting the first data by reflecting a collection condition under which the first data is collected, and determining whether the wobbling is normal by comparing the second data with SPC (Statistical Process Control) data, wherein the SPC data is derived using data on the position of the reflection image measured at a predetermined time interval over a predetermined period under a predetermined collection condition, and wherein the second data is corrected on the basis of the collection condition of the SPC data.

At this time, the SPC data may be derived using an average absolute deviation of data on the position of the reflection image measured at the predetermined time interval over the predetermined period.

Also, the SPC data may include information on a plurality of wobbling levels that classifies a degree of the wobbling in a stepwise manner.

Acquiring the wafer surface image may acquire the wafer surface image in which the reflection images, where a plurality of fixed objects is reflected on the surface of the wafer, are included, extracting the plurality of reflection images as an object by an artificial intelligence algorithm trained from the acquired image may be further performed after acquiring the wafer surface image, and detecting the wobbling of the wafer may analyze at least one position of the extracted objects.

At this time, after extracting the reflection image as the object, selecting at least one among the plurality of extracted reflection images as a reflection image to be analyzed may be further included, wherein the selecting step is performed by the trained artificial intelligence algorithm.

The artificial intelligence algorithm used in the selecting step may select the reflection image to be analyzed on the basis of a sharpness of a contour of the extracted reflection images.

The selecting step may include selecting and recommending the at least reflection image to be analyzed by the artificial intelligence algorithm, and receiving a confirmation with respect to the recommended reflection image to be analyzed, wherein the received confirmation is additionally reflected and trained in a training process of the artificial intelligence algorithm for selecting the reflection image to be analyzed.

A lower limit may be set for the ratio of the detection color region included in the detection region and, when the ratio of the detection color region included in the detection region is lower than the lower limit, it may be determined that abnormal wobbling is occurring.

A wafer wobble detection system according to another aspect of the present disclosure is a wafer wobble detection method applicable to semiconductor equipment that performs a process while rotating an internally mounted wafer, the system including: a fixed object installed inside equipment and having a fixed position; a camera for acquiring a wafer surface image to include a reflection image, where the fixed object is reflected on a surface of a wafer; and a machine vision analyzer for detecting wobbling of the wafer by analyzing the acquired image, wherein the machine vision analyzer detects the wobbling of the wafer by analyzing a position of the reflection image that moves due to the wobbling in the acquired image, and detects the wobbling by setting a detection region at a predetermined position of an image, setting a color of the reflection image as a detection color, and calculating a ratio of a detection color region included in the detection region, wherein the detection region is set on the basis of the position of the reflection image.

The machine vision analyzer may perform analysis using an image converted to a gray scale, and the detection color is the color of the reflection image converted to the gray scale.

The machine vision analyzer may perform a process of converting the image into the gray scale and adjusting the gray scale of the image to a reference scale, wherein the reference scale is set on the basis of the color of the wafer and the color of the wafer in a captured image is adjusted to match the reference scale.

At this time, the image may be an image to which image interpolation is applied.

The machine vision analyzer may acquire a first data on the position of the reflection image, produce a second data by correcting the first data by reflecting a collection condition under which the first data is collected, and determine whether the wobbling is normal by comparing the second data with SPC (Statistical Process Control) data, wherein the SPC data is derived using data on the position of the reflection image measured at a predetermined time interval over a predetermined period under a predetermined collection condition, and wherein the second data is corrected on the basis of the collection condition of the SPC data.

At this time, the SPC data may be derived using an average absolute deviation of data on the position of the reflection image measured at the predetermined time interval over the predetermined period.

Also, the SPC data may include information on a plurality of wobbling levels that classifies a degree of the wobbling in a stepwise manner.

The fixed objects may be installed in plurality such that the wafer surface image includes the plurality of reflection images, and a reflection image extraction unit for extracting the plurality of reflection images as an object from the acquired image may be further included, wherein the reflection image extraction unit includes a reflection image extraction algorithm that is a trained artificial intelligence algorithm.

At this time, a target selection unit may be further included that selects at least one among the plurality of objects extracted from the reflection image extraction unit as a reflection image to be analyzed, wherein the target selection unit includes a target selection algorithm that is a trained artificial intelligence algorithm.

The target selection algorithm may select the reflection image to be analyzed on the basis of a sharpness of a contour of the extracted reflection images.

Furthermore, the target selection unit may include a recommendation unit for selecting and recommending the at least reflection image to be analyzed by the target selection algorithm, and a confirmation unit for receiving a confirmation with respect to the recommended reflection image to be analyzed, wherein a feedback of the confirmation unit is additionally reflected and trained in a training process of the target selection algorithm.

The machine vision analyzer may set a lower limit for the ratio of the detection color region included in the detection region and, when the ratio of the detection color region included in the detection region is lower than the lower limit, it may be determined that abnormal wobbling is occurring.

The present disclosure described above may have an effect of detecting the wobbling of the wafer while a process is in progress on the wafer by analyzing images captured of the rotating wafer using machine vision.

In addition, since wafer wobbling can be detected while the process is in progress on the wafer, there is the further advantageous effect of taking measures such as stopping the equipment in real time when abnormal wobbling is occurring.

### BRIEF DESCRIPTION OF THE DRAWINGS

FIG. 1 is a view illustrating a structure of a wafer wobble detection system according to the present disclosure.

FIG. 2 is a view illustrating a detection method based on a position of a reflection image in a wafer wobble detection system according to a first exemplary embodiment of the present disclosure.

FIG. 3 is a view illustrating a stepwise change of a boundary line caused by image interpolation.

### DETAILED DESCRIPTION OF THE DISCLOSURE

Hereinafter, exemplary embodiments according to the present disclosure will be described in detail with reference to the accompanying drawings.

However, the exemplary embodiments of the present disclosure may be modified in various ways, and the scope of the present disclosure may not be limited to the exemplary embodiments described below. The shape and size of the elements in the drawing may be exaggerated for clearer explanation, and the elements indicated by the same reference numerals in the drawing may be the same elements.

Also, when a part is “connected” to another part throughout the specification, this may include not only the cases where it is “directly connected” but also the cases where it is “electrically connected” with other elements interposed therebetween. In addition, when a part “includes” or “has” a component, it may include or have other components, rather than excluding other components unless otherwise stated.

In addition, terms such as “first” and “second” may be intended to distinguish one component from another component, and the scope of rights should not be limited by these terms. For example, a first component may be referred to as a second component, and similarly, the second component may also be referred to as the first component.

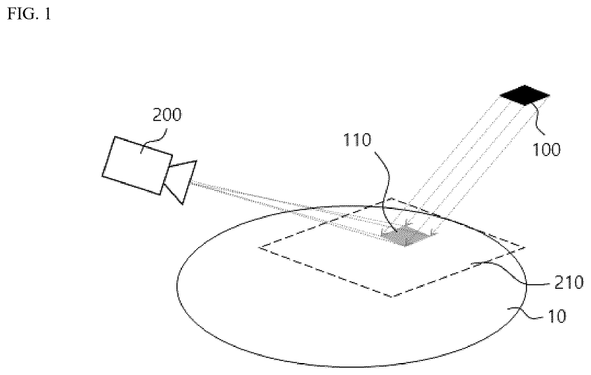

FIG. 1 is a view illustrating a structure of a wafer wobble detection system according to the present disclosure.

A wafer wobble detection system according to an exemplary embodiment of the present disclosure may include a fixed object 100, a camera 200, and a machine vision analyzer (not shown).

A target on which the wobbling detection system of the present exemplary embodiment is installed can be any semiconductor equipment in which a wafer rotates during a processing operation, and may not be particularly limited as long as it does not depart from the spirit and scope of the present disclosure.

The fixed object 100 may be installed inside the semiconductor equipment and may serve as a component where a reflection image 110 of the fixed object 100 reflected on the surface of the wafer 10 captured by the camera 200 is captured. Since the position and the like may not be particularly limited so long as the reflection image 110 of the fixed object 100 can be identified within a capture region 210 captured by the camera 200, the fixed object 100 may be a structure originally installed inside the equipment, but it is preferable that the fixed object is a component added separately to increase identification, and in the present exemplary embodiment, a square sticker may be attached to an inner wall of the equipment chamber.

The camera 200 may be a component that captures images for detecting wobbling, and may capture images such that at least a portion of the rotating wafer 10 is included within the capture region 210. The camera used in the present disclosure may not be particularly limited as long as it has a resolution capable of supporting image analysis by machine vision. In the present disclosure, the capture region 210 captured by the camera 200 may be important and, specifically, the camera 200 may be installed such that the reflection image 110 of the fixed object 100 reflected on the surface of the wafer 10 is included within the capture region 210.

At this time, the movement of the wafer surface may increase due to wobbling as the distance from the center of the wafer 10 increases, so the wobbling can be detected more effectively when the reflection image 110 of the fixed object 100 is positioned closer to the edge of the wafer. Accordingly, it is preferable to adjust the relative position and angle of the fixed object 100 and the camera 200 such that the reflection image 110 of the fixed object 100 is positioned toward the outer edge of the wafer 10 and, in particular, it is preferable that the distance of the reflection image 110 from the center of the wafer in the image captured by the camera 200 be 60% or more of the wafer radius, it is more preferable that the distance of the reflection image 110 from the center of the wafer be 70% or more of the wafer radius, and it is even more preferable that the distance of the reflection image 110 from the center of the wafer be 80% or more of the wafer radius. Meanwhile, when the reflection image 110 of the fixed object 100 is positioned excessively close to the outer edge of the wafer 10, there is a problem that the reflection image moves beyond the region of the wafer due to the wobbling and thus fails to be detected, so it is preferable that the distance of the reflection image 110 from the center of the wafer be 95% or less of the wafer radius.

The machine vision analyzer may be a component for detecting the wobbling of the rotating wafer 10 by analyzing an image captured by the camera. Since the position of the camera 200 is fixed, the surface angle of the rotating wafer 10 with respect to the camera 200 may continuously change due to the wobbling and accordingly, the reflection image 110 of the fixed object 100 reflected on the surface of the wafer 10 in the captured image may also inevitably move rather than remaining stationary. Therefore, the wobbling of the wafer can be detected by identifying the position and movement of the reflection image 110 in the image capturing the surface of the wafer. A method of detecting the position of the reflection image 110 by the machine vision analyzer may be applied in various ways, and a method through pixel detection may be applied.

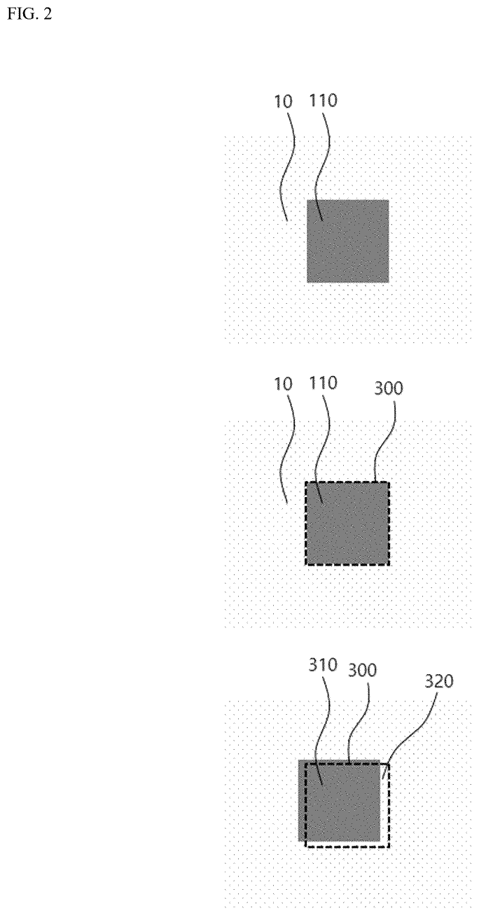

FIG. 2 is a view illustrating a detection method based on a position of a reflection image in a wafer wobble detection system according to a first exemplary embodiment of the present disclosure.

The first illustration of FIG. 2 is an image captured by the camera 200 of FIG. 1, and a reflection image 110 and a wafer 10 are captured in the captured image.

In the present exemplary embodiment, as shown in the second illustration, a detection region 300 may be set on the basis of the reflection image 110. The detection region 300 may be a region from which data is obtained for determining the movement of the reflection image 110 and detecting abnormal wobbling. The detection region 300 may be set in various ways, but may be set on the basis of the position of the reflection image 110 and, for example, may be a range in which the reflection image 110 is positioned when abnormal wobbling does not occur, or may be the position of the reflection image 110 captured when the wafer is not rotating, as illustrated. Accordingly, the detection region 300 may be the same size as the reflection image, or may be set to be relatively larger than the reflection image.

Along with the setting of the detection region 300, the color of the reflection image 110 may be set and stored as a detection color. At this time, the detection color may be the color of the reflection image 110 in the captured image, so may be set differently depending on the type of captured image and, preferably, may be set to the color represented by the reflection image 110 in a grayscale version of the captured image.

In the present exemplary embodiment, the wobbling may be detected by calculating the ratio of the detection color with respect to the detection region 300 after setting the detection region 300 and the detection color.

As shown in the third illustration, when the semiconductor equipment operates and rotates the wafer, the position of the reflection image may move due to the wobbling. When this is limited within the detection region 300, the region can be divided into a detection color region 310, which represents the detection color corresponding to the reflection image, and a non-detection color region 320, which does not represent the detection color because it becomes vacant as the reflection image moves. Ultimately, by calculating the ratio of the detection color—that is, the ratio of the detection color region 310—within the detection region 300, the degree of movement of the reflection image can be derived, and the wobbling can be detected on the basis of this value.

For example, the machine vision analyzer may calculate the ratio of the detection color region 310 with respect to the detection region 300 in real time, and may determine that abnormal wobbling is occurring when the ratio of the detection color region 310 with respect to the detection region 300 is lower than a predetermined value. Furthermore, when such abnormal wobbling is occurring, the operation of the semiconductor equipment may be configured to stop by determining that a device malfunction or a wafer mounting error occurs.

The ratio of the detection color region 310 with respect to the detection region 300 for determining whether abnormal wobbling is occurring may be set on the basis of yield data. For example, the ratio of the detection color region 310 with respect to the detection region 300, which is measured when a yield is lower than a predetermined yield (e.g., 90% or more yield) using a yield indicating a defect rate of the process, may be derived as a criterion for determining abnormal wobbling. The criterion for determining the abnormal wobbling may not be limited to yield data, and may be applied on the basis of process time or material cost, or may be applied with two or more criteria together.

Meanwhile, since the surface of the wafer 10 does not exhibit mirror-like reflective characteristics, the reflection image 110 may be affected not only by diffuse reflection but the reflection image 110 may also be distorted by the flow of liquid applied to the surface of the wafer 10 during processing. Accordingly, the size of the reflection image 110 may not be exactly identical to the detection region 300, and the detection region 300 may be formed to be slightly smaller or larger than the reflection image within a predetermined range.

The wafer wobble detection system according to the second exemplary embodiment of the present disclosure may include a configuration for increasing accuracy and setting convenience in the process of detecting the position of the reflection image.

The configuration of the wafer wobble detection system according to the present exemplary embodiment may be the same as that illustrated in FIG. 1, and therefore, a redundant description of identical elements will be omitted.

The image analysis performed in the vision analyzer of the wafer wobble detection system according to the present exemplary embodiment may be generally performed by applying improved images such as image interpolation, but slight errors may occur in the size and position of the reflection image 110 due to the influence of image interpolation, etc.

Basically, the present disclosure may be performed by analyzing images captured of the wafer, and the externally visible color of the wafer may vary depending on the stage of the process being performed. As various semiconductor processes are performed, ultrafine patterns may be formed on the surface of the wafer or additional materials may be deposited thereon, and due to these effects, the externally visible color of the wafer may change in various ways.

At this time, in the process of analyzing the image to detect the position of the reflection image, the image may be usually converted to gray scale and analyzed, but due to the color difference of the wafer as described above, the color of the wafer may appear different even in the image converted to gray scale.

Meanwhile, as described above, the image interpolation may be performed during the image analysis process, and when the boundary of the reflection image is magnified at the pixel level, it is common for the color to change stepwise due to the image interpolation.

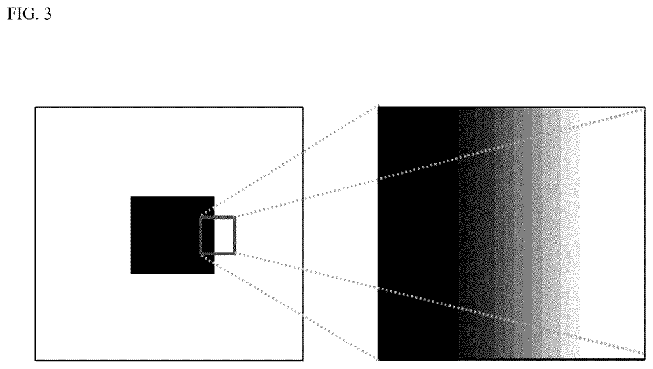

FIG. 3 is a view illustrating a stepwise change of a boundary line caused by image interpolation.

At this time, due to the aforementioned difference in wafer color, the stepwise-changing boundary of the reflection image may be recognized differently. To prevent such issues, it is preferable to adjust the grayscale of the image so that the boundary line can be clearly defined.

In the present exemplary embodiment, the gray scale of the wafer derived from a predetermined reference image may be set as a reference, and the gray scale may be adjusted by a method of matching the colors of the wafer in the image to be analyzed. The reference image may be an image with respect to a wafer for which the program settings for the boundary line analysis are known, and the program settings can be applied directly to the reference scale which is the gray scale to which the color of the wafer corresponding to this image is converted. According to this process, since the gray scale of the wafer as a background is the same as the reference scale, which is the gray scale of the reference image, there is no need to change the setting of the program for analyzing the boundary line, even when the color of the wafer to be analyzed is different.

The wafer wobble detection system according to the third exemplary embodiment of the present disclosure may include a configuration for applying data processing to enable wobbling detection by integrating even cases where the installation position of the camera or other conditions differ.

The configuration of the wafer wobble detection system according to the present exemplary embodiment may be the same as that illustrated in FIG. 1, and therefore, a redundant description of identical elements will be omitted.

A method of detecting wobbling by the machine vision analyzer in the present exemplary embodiment may acquire a first data with respect to a position of the reflection image.

At this time, the first data on the position of the reflection image may not reflect any determination as to whether wobbling is abnormal, and may purely contain information on the position of the reflection image. The first data may be continuously acquired at predetermined time intervals as the process proceeds, and the process of determining the wobbling in the present exemplary embodiment may be performed using a single piece of first data individually or performed using a group of multiple pieces of first data. The method of acquiring information on the position of the reflection image 110 by the machine vision analyzer may be applied in various ways, and a method through pixel detection may be applied.

The machine vision analyzer may acquire the first data on the position of the reflection image by calculating, in real time, the ratio of each region to which the reflection image belongs and quantifying this information. Thereafter, the processes of setting the detection region 300 and the detection color and calculating the ratio of the detection color with respect to the detection region 300, may be the same. The position of the reflection image can be derived by calculating the ratio of the detection color—i.e., the ratio of the detection color region 310—in the range of the detection region 300, and may be quantified and acquired as the first data with respect to the position of the reflection image.

Meanwhile, the installation position of the camera may be changed due to the characteristics of equipment and process, and differences in the installation position of the camera may result in variations in height, angle, distance, background, and the like in the acquired images. Accordingly, when the camera installation position is changed, the values of the first data acquired by the method illustrated in FIG. 2 may also differ. Consequently, even when the reflection image actually moves as much as the same, the difference in camera installation positions may cause the values of the first data to vary, and when the wobbling is determined on the basis of such values, a problem may occur in which the determination results are also different.

In order to prevent such a problem in the present exemplary embodiment, the second data may be derived by correcting the first data on the basis of the collection conditions under which the position information is acquired. The collection conditions for acquiring the position information may reflect the installation position of the camera, and may reflect factors such as the camera installation height, angle, and distance from the reflection image. The method of correcting the first data where the camera installation position is reflected may be applied in various ways without departing from the spirit of the present disclosure, and a predetermined algorithm may be applied to be automatically calculated. In this case, the collection condition as a reference for correction may be based on the collection condition of the SPC data to be described later.

Finally, the second data where correction is completed for the collection conditions may be compared with SPC (Statistical Process Control) data to determine whether the wobbling is normal.

The SPC data may be the standard data for determining wobbling, and may be derived using data on the position of the reflection image measured at a predetermined time interval over a predetermined period under a predetermined collection condition and, for example, may be derived using the average absolute deviation of the data on the position of the reflection image measured at the predetermined time interval over the predetermined period. Also, the conditions under which the SPC data is collected may be applied as the correction conditions in the process of producing the second data described above. Accordingly, even when the installation positions of the cameras in the equipment for which the wobbling is being detected and in the equipment used to collect the SPC data are different, the SPC data can still be used as the reference data for wobbling detection.

The SPC data may be derived in the form of a control chart, and the values of the second data described above can be used to determine whether the wobbling is normal. At this time, the SPC data may include information on a plurality of wobbling levels that classifies the degree of wobbling in a stepwise manner, and even when the normal wobbling is occurring, the condition of the equipment may be determined on the basis of the wobbling level.

The wafer wobble detection system according to a fourth exemplary embodiment of the present disclosure may be configured to attach a plurality of fixed objects in order to improve the performance of wobbling detection.

The wafer wobble detection system according to the present exemplary embodiment may include the configuration illustrated in FIG. 1, and may further be configured to include a reflection image extraction unit (not shown) and a target selection unit (not shown). Other configurations other than the reflection image extraction unit and the target selection unit may be almost the same as those of the above-described exemplary embodiment, and therefore, a redundant description of identical elements will be omitted.

The present exemplary embodiment may be configured to attach a plurality of fixed objects 100 and capture a plurality of reflection images 110 from one or more captured images, and when the plurality of fixed objects are attached to different positions, positions at which reflection images are disposed for each may also be variously distributed. In this way, the reflection images reflected from different positions on the wafer surface may exhibit different movements due to the rotation and wobbling of the wafer, so it is possible to improve the performance of wobbling detection. In this case, wobbling detection may be performed by selecting one that provides superior wobbling detection performance among the plurality of reflection images.

The reflection image extraction unit may be a component for extracting the reflection image 110 included in the captured image as objects. The process of extracting the reflection image 110 as objects may be performed by a trained artificial intelligence algorithm, and for this purpose, a reflection image extraction algorithm may be included in the reflection image extraction unit. In this case, the artificial intelligence algorithm for extracting the reflection image 110 as objects may not be particularly limited and various approaches may be applied without departing from the spirit of the present disclosure. For example, sensor parameters may be vectorized and trained using a recurrent neural network (RNN)-based deep learning model. More specifically, in order to utilize image information, an image of a region of interest may be extracted and trained using a CNN or a transformer-based algorithm. In this case, the tool region of the vision sensor may be expanded to extract and vectorize the images, which is utilized as input data for deep learning.

When the plurality of fixed objects is attached such that the plurality of reflection images is captured, the plurality of reflection images may be extracted as objects.

The target selection unit may be a component for selecting one or more reflection images as the reflection image to be analyzed when the plurality of reflection images is extracted as objects.

The process of selecting the reflection image to be analyzed may be performed by the trained artificial intelligence algorithm, and for this purpose, the target selection algorithm may be included in the target selection unit. In this case, the artificial intelligence algorithm for selecting the reflection image to be analyzed may not be particularly limited and various approaches may be applied without departing from the spirit of the present disclosure. For example, the reflection images to be analyzed can be selected by evaluating the sharpness of the contours of the plurality of extracted reflection images. Specifically, the sharpness of the contours of the plurality of extracted reflection images may be evaluated to select reflection images having a sharpness equal to or greater than a predetermined threshold as analysis targets, or to select the top-ranked reflection images having high contour sharpness as analysis targets. Meanwhile, the process of selecting the reflection image to be analyzed may include a process in which the artificial intelligence algorithm recommends the reflection image to be analyzed by the recommendation unit, and a user checks and gives feedback on the recommended reflection image to be analyzed, and the confirmation unit may receive user's feedback and reflect the same in the training process of an artificial intelligence algorithm that selects the reflection image to be analyzed. Through this process, it is possible to improve the training effect of the artificial intelligence algorithm that selects the reflection image to be analyzed. An attention algorithm may be applied in order to maintain optimal training accuracy in the training process of the artificial intelligence algorithm that selects the reflection image to be analyzed.

The present disclosure has been described above through preferred exemplary embodiments, but the above-described exemplary embodiments may be merely illustrative of the technical idea of the present disclosure, and it will be understood by those of ordinary skill in the art that various changes are possible without departing from the technical idea of the present disclosure. Therefore, the scope of protection of the present disclosure should be interpreted by the matters described in the claims, not by specific exemplary embodiments, and all technical ideas within the equivalent scope should be interpreted as being included in the scope of the present disclosure.

What is claimed is:

1. A wafer wobble detection method applicable to semiconductor equipment that performs a process while rotating an internally mounted wafer, the method comprising:
acquiring a wafer surface image to include a reflection image, where a fixed object installed inside equipment and having a fixed position is reflected on a surface of a wafer; and
detecting wobbling of the wafer by analyzing a position of the reflection image that moves due to wobbling in the acquired image,
wherein analyzing the position of the reflection image comprises:
setting a detection region at a predetermined position of an image and setting a color of the reflection image as a detection color; and
calculating a ratio of a detection color region included in the detection region,
wherein the detection region is set on the basis of the position of the reflection image.

2. The method of claim 1, wherein, in the process of analyzing the position of the reflection image, the image is an image converted to a gray scale, and the detection color is the color of the reflection image converted to the gray scale.

3. The method of claim 2, further performing:
adjusting the converted grayscale to a reference scale,
wherein the reference scale is set on the basis of a color of the wafer and the color of the wafer in a captured image is adjusted to match the reference scale.

4. The method of claim 3, wherein the image is an image to which image interpolation is applied.

5. The method of claim 1, wherein detecting the wobbling comprises:
acquiring a first data on the position of the reflection image;
producing a second data by correcting the first data by reflecting a collection condition under which the first data is collected; and
determining whether the wobbling is normal by comparing the second data with SPC (Statistical Process Control) data,
wherein the SPC data is derived using data on the position of the reflection image measured at a predetermined time interval over a predetermined period under a predetermined collection condition, and
wherein the second data is corrected on the basis of the collection condition of the SPC data.

6. The method of claim 5, wherein the SPC data is derived using an average absolute deviation of data on the position of the reflection image measured at the predetermined time interval over the predetermined period.

7. The method of claim 5, wherein the SPC data comprises information on a plurality of wobbling levels that classifies a degree of the wobbling in a stepwise manner.

8. The method of claim 1, wherein acquiring the wafer surface image acquires the wafer surface image in which the reflection images, where a plurality of fixed objects is reflected on the surface of the wafer, are included,
extracting the plurality of reflection images as an object by an artificial intelligence algorithm trained from the acquired image is further performed after acquiring the wafer surface image, and
detecting the wobbling of the wafer analyzes at least one position of the extracted objects.

9. The method of claim 8, further comprising:
selecting at least one among the plurality of extracted reflection images as a reflection image to be analyzed after extracting the reflection image as the object,
wherein the selecting step is performed by the trained artificial intelligence algorithm.

10. The method of claim 9, wherein the artificial intelligence algorithm used in the selecting step selects the reflection image to be analyzed on the basis of a sharpness of a contour of the extracted reflection images.

11. The method of claim 9, wherein the selecting step comprises:
selecting and recommending the at least reflection image to be analyzed by the artificial intelligence algorithm; and
receiving a confirmation with respect to the recommended reflection image to be analyzed,
wherein the received confirmation is additionally reflected and trained in a training process of the artificial intelligence algorithm for selecting the reflection image to be analyzed.

12. The method of claim 1, wherein a lower limit is set for the ratio of the detection color region included in the detection region and, when the ratio of the detection color region included in the detection region is lower than the lower limit, it is determined that abnormal wobbling is occurring.

13. A wafer wobble detection system applicable to semiconductor equipment that performs a process while rotating an internally mounted wafer, the system comprising:
a fixed object installed inside equipment and having a fixed position;
a camera for acquiring a wafer surface image to include a reflection image, where the fixed object is reflected on a surface of a wafer; and
a machine vision analyzer for detecting wobbling of the wafer by analyzing the acquired image,
wherein the machine vision analyzer detects the wobbling of the wafer by analyzing a position of the reflection image that moves due to the wobbling in the acquired image, and
detects the wobbling by setting a detection region at a predetermined position of an image, setting a color of the reflection image as a detection color, and calculating a ratio of a detection color region included in the detection region,
wherein the detection region is set on the basis of the position of the reflection image.

14. The system of claim 13, wherein the machine vision analyzer performs analysis using an image converted to a gray scale, and the detection color is the color of the reflection image converted to the gray scale.

15. The system of claim 14, wherein the machine vision analyzer performs a process of converting the image into the gray scale and adjusting the gray scale of the image to a reference scale,
wherein the reference scale is set on the basis of the color of the wafer and the color of the wafer in a captured image is adjusted to match the reference scale.

16. The system of claim 15, wherein the image is an image to which image interpolation is applied.

17. The system of claim 13, wherein the machine vision analyzer acquires a first data on the position of the reflection image, produces a second data by correcting the first data by reflecting a collection condition under which the first data is collected, and determines whether the wobbling is normal by comparing the second data with SPC (Statistical Process Control) data,
wherein the SPC data is derived using data on the position of the reflection image measured at a predetermined time interval over a predetermined period under a predetermined collection condition, and
wherein the second data is corrected on the basis of the collection condition of the SPC data.

18. The system of claim 17, wherein the SPC data is derived using an average absolute deviation of data on the position of the reflection image measured at the predetermined time interval over the predetermined period.

19. The system of claim 17, wherein the SPC data comprises information on a plurality of wobbling levels that classifies a degree of the wobbling in a stepwise manner.

20. The system of claim 13, wherein the fixed object is installed in plurality such that the wafer surface image comprises the plurality of reflection images, and
further comprising a reflection image extraction unit for extracting the plurality of reflection images as an object from the acquired image,
wherein the reflection image extraction unit comprises a reflection image extraction algorithm that is a trained artificial intelligence algorithm.

21. The system of claim 20, further comprising:
a target selection unit for selecting at least one among the plurality of objects extracted from the reflection image extraction unit as a reflection image to be analyzed,
wherein the target selection unit comprises a target selection algorithm that is a trained artificial intelligence algorithm.

22. The system of claim 21, wherein the target selection algorithm selects the reflection image to be analyzed on the basis of a sharpness of a contour of the extracted reflection images.

23. The system of claim 21, wherein the target selection unit comprises:
a recommendation unit for selecting and recommending the at least reflection image to be analyzed by the target selection algorithm; and
a confirmation unit for receiving a confirmation with respect to the recommended reflection image to be analyzed,
wherein a feedback of the confirmation unit is additionally reflected and trained in a training process of the target selection algorithm.

24. The system of claim 13, wherein the machine vision analyzer sets a lower limit for the ratio of the detection color region included in the detection region and, when the ratio of the detection color region included in the detection region is lower than the lower limit, it is determined that abnormal wobbling is occurring.
